(19) United States
(12) Patent Application Publication
(10) Pub. No.: US 2008/0203564 A1
(43) Pub. Date: Aug. 28, 2008

(54) Semiconductor device having stress alleviating portion positioned at outer circumference of chip, wiring substrate, and method for producing the same

(75) Inventors: Souichirou Motoyoshi, Kanagawa (JP); Hirokazu Honda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/068,438

(22) Filed: Feb. 6, 2008

(30) Foreign Application Priority Data
Feb. 23, 2007 (JP) 2007-043292

(51) Int. Cl. H01L 23/488; H01L 21/56; H05K 1/00

(52) U.S. Cl. 257/737; 438/117; 174/261; 257/E23.024; 257/E21.502

(57) ABSTRACT

A semiconductor device has a wiring substrate, a semiconductor chip, a conductive bump, and an under-fill resin. The wiring substrate has a solder resist layer, and a stress alleviating portion. The stress alleviating portion is mounted on the solder resist layer opposed to the outer circumference of the semiconductor chip. The material of the stress alleviating portion is different from that of the solder resist layer. The stress alleviating portion alleviates the stress acting on the solder resist layer and the under-fill resin. The semiconductor chip is mounted above the wiring substrate via the conductive bump. The gap between the wiring substrate and the semiconductor chip is filled with the under-fill resin.

### BACKGROUND OF THE INVENTION

1. Field of the Invention

The present invention relates to a semiconductor device, a wiring substrate, and a method for producing the same.

2. Description of Related Art

FIG. 14 is a cross-sectional view showing a semiconductor device of a related art. FIG. 14 shows a potion at an outer circumference of a semiconductor chip 120. In a semiconductor device 100, a semiconductor chip 120 is mounted on a wiring substrate 110 with a solder bump 130 disposed in between. In the wiring substrate 110, a solder resist layer 112 and an electrode pad 114 connected with the solder bump 130 are formed. A gap between the wiring substrate 110 and the semiconductor 120 is filled with an under fill resin 140.

The following are the documents 1 and 2 as related art.

[Patent Document 1] Japanese Patent Application Laid-open Publication No. 2006-253315

[Patent Document 2] Japanese Patent Application Laid-open Publication No. 2002-118208

However, in the above described semiconductor device 100, a stress is generated due to the difference in thermal expansion coefficient between the wiring substrate 110 and the semiconductor chip 120. The stress is particularly increased near the outer circumference of the semiconductor 120. As a result, in the portion, peeling tends to be occurred at the interface between the solder resist layer 112 and the under-fill resin 140. In FIG. 14, appearance in which such peeling is actually occurred in the portion (a portion surrounded by a dotted line L1) is diagrammatically shown.

### SUMMARY OF THE INVENTION

A semiconductor device has a wiring substrate and a semiconductor chip mounted on the wiring substrate with a conductive bump disposed in between. The device includes: a solder resist layer mounted on the wiring substrate; a stress alleviating portion which is mounted in the area of the solder resist layer opposed to the outer circumference of the semiconductor chip, and is made of a material different from that of the solder resist layer; and an under-fill resin which fills the gap between the wiring substrate and the semiconductor chip. In the device, the stress alleviating portion has a function of alleviating a stress acting on the solder resist layer and the under-fill resin.

In the semiconductor device, the stress alleviating portion is mounted in the area of the solder resist layer opposed to the outer circumference of the semiconductor chip. The stress alleviating portion alleviates a stress acting on the solder resist layer and the under-fill resin. As a result, peeling is hardly occurred at the interface between the solder resist layer and the under-fill resin.

A wiring substrate mounts the semiconductor chip with the conductive bump disposed in between. The substrate includes the solder resist layer, and the stress alleviating portion which is mounted in the area of the solder resist layer opposed to the outer circumference of the semiconductor chip, and is made of a material different from that of the solder resist layer.

In the wiring substrate, the stress alleviating portion is mounted in the area of the solder resist layer opposed to the outer circumference of the semiconductor chip. In the semiconductor device in which the wiring substrate is used, the stress alleviating portion alleviates a stress acting on the solder resist layer and the under-fill resin. As a result, peeling (e.g. peel-off) is hardly occurs at the interface between the solder resist layer and the under-fill resin.

A semiconductor production method includes forming a solder resist layer on a wiring substrate; forming a stress alleviating portion, which is made of a material different from that of the solder resist layer, in the area of the solder resist layer opposed to the outer circumference of a semiconductor chip; mounting the semiconductor chip above the wiring substrate via a conductive bump; and filling the gap between the wiring substrate and the semiconductor chip with an under-fill resin. The stress alleviating portion has a function of alleviating the stress acting on the solder resist layer and the under-fill resin.

In the production method, the stress alleviating portion is formed in the area of the solder resist layer opposed to the outer circumference of the semiconductor chip. The stress alleviating portion alleviates the stress acting on the solder resist layer and the under-fill resin. As a result, in the semiconductor device produced in the method, peeling hardly occurs at the interface between the solder resist layer and the under-fill resin.

A wiring substrate production method includes forming a solder resist layer, and forming a stress alleviating portion, which is made of a material different from that of the solder resist layer, in the area of the solder resist layer opposed to the outer circumference of a semiconductor chip.

In the production method, the stress alleviating portion is formed in the area of the solder resist layer opposed to the outer circumference of the semiconductor chip. In the semiconductor device in which the wiring substrate produced by the method is used, the stress alleviating portion alleviates the stress acting on the solder resist layer and the under-fill resin. As a result, peeling hardly occurs at the interface between the solder resist layer and the under-fill resin.

According to the present invention, a reliable semiconductor device, a reliable wiring substrate, and a method for producing the same are realized.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a cross-sectional view showing the first embodiment of the semiconductor device according to the present invention;

FIG. 2 is a plan view showing the first embodiment of the semiconductor device according to the present invention;

FIG. 3 is a plan view showing a wiring substrate;

FIGS. 4A through 4C are a flow chart showing an example of the production method of the semiconductor device in FIG. 1;

FIGS. 5A and 5B are a flow chart showing an example of the production method of the semiconductor device in FIG. 1;

FIG. 6 is a cross-sectional view showing the second embodiment of the semiconductor device according to the present invention;

FIGS. 7A through 7C are a flow chart showing an example of the production method of the semiconductor device in FIG. 6;

FIGS. 8A and 8B are a flow chart showing an example of the production method of the semiconductor device in FIG. 6;

FIG. 9 is a cross-sectional view showing the third embodiment of the semiconductor device according to the present invention;

FIGS. 10A through 10C are a flow chart showing an example of the production method of the semiconductor device in FIG. 9;

FIGS. 11A and 11B are a flow chart showing an example of the production method of the semiconductor device in FIG. 9;

FIG. 12 is a plan view for describing an example of the modification of an embodiment;

FIG. 13 is a plan view for describing an example of the modification of an embodiment; and

FIG. 14 is a cross-sectional view showing the conventional semiconductor device.

### DETAILED DESCRIPTION OF THE EXEMPLARY EMBODIMENTS

### Embodiment 1

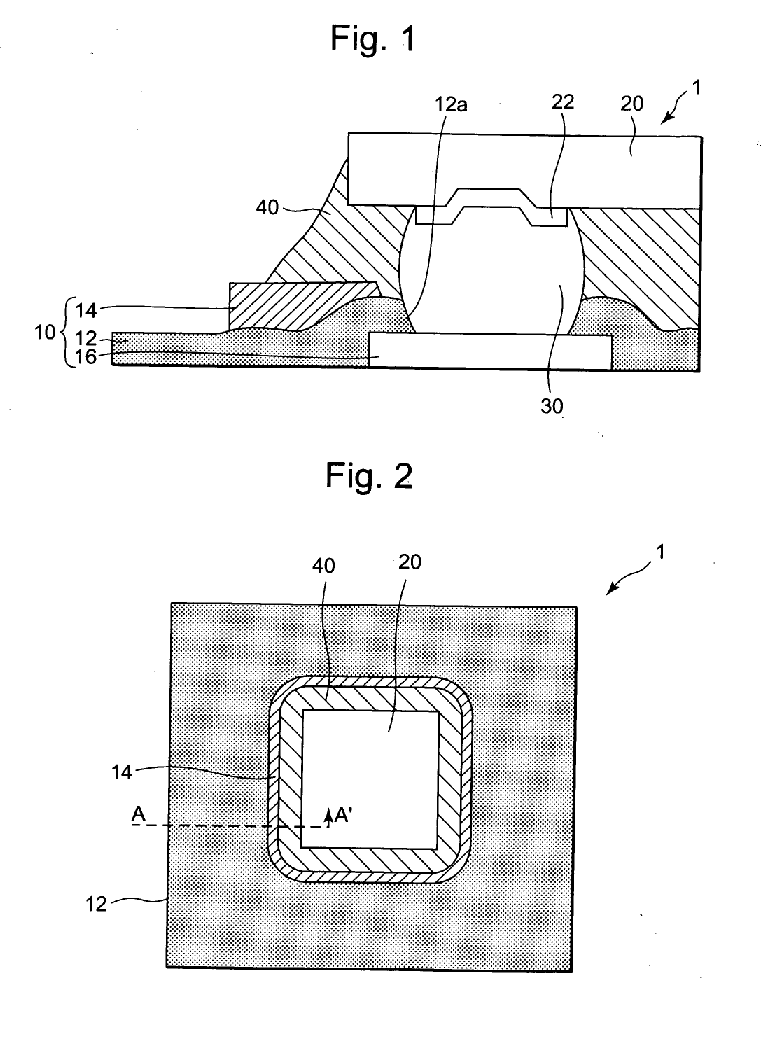

FIGS. 1 and 2 are a cross-sectional view and a plan view which show a first embodiment of the semiconductor device according to the present invention, respectively. FIG. 1 corresponds to a line A-A′ of FIG. 2. A semiconductor device 1 comprises a wiring substrate 10, a semiconductor chip 20, a conductive bump 30, and an under-fill resin 40.

The wiring substrate 10 includes a solder resist layer 12, a stress alleviating portion 14, and an electrode pad 16. In the solder resist layer 12, an opening 12a is formed. The opening 12a is located on the electrode pad 16. In the present embodiment, the marginal portions of the electrode pad 16 are covered with the solder resist layer 12. That is, in the wiring substrate 10, SMD (Solder Mask Define) structure is realized. As the material of the solder resist layer 12, for example, epoxy-based resin can be used.

In the area (that is, an area overlapping with the outer circumference in a plan view) of the solder resist layer 12 opposed to the outer circumference of the semiconductor chip 20, the stress alleviating portion 14 is mounted. The stress alleviating portion 14 has a function of alleviating the stress acting on the solder resist layer 12 and the under-fill resin 40. The stress alleviating portion 14 is constructed as a resin layer. The material of the stress alleviating portion 14 is difference from that of the solder resist layer 12. As the material of the stress alleviating portion 14, for example, acryl-based resin, or silicon-based resin can be used. Alternatively, a hybrid resin of epoxy and acryl, or a hybrid resin of epoxy and silicon can be used as the material of the stress alleviating portion 14.

The stress alleviating portion 14 preferably has a lower degree of elasticity than the solder resist layer 12. The values of the degree of elasticity (Young's modulus) of the solder resist layer 12 and the stress alleviating portion 14 are, for example, 3 to 10 GPa and 0.01 to 3 Gpa, respectively.

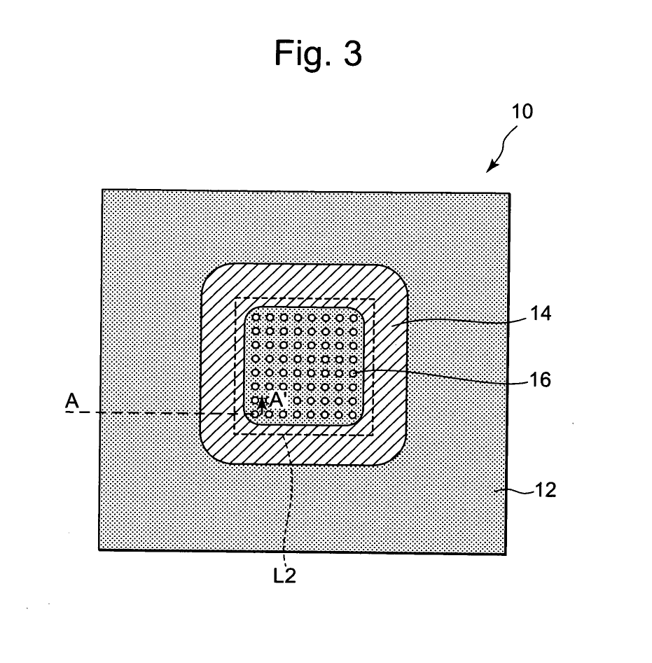

FIG. 3 is a plan view showing the wiring substrate 10, which is removed the semiconductor chip 20 and the under-fill resin 40 from FIG. 1 and FIG. 2. A dotted line L2 represents the outer circumference of the semiconductor chip 20. As seen from FIG. 3, the stress alleviating portion 14 is mounted over the entire of the outer circumference of the semiconductor chip 20. The stress alleviating portion 14 is mounted only outside of an area in which the electrode pad 16 is exposed. This means that the stress alleviating portion 14 is present only outside of the conductive bump 30 (to be more specifically, the outermost circumference of the conductive bump 30) in the semiconductor device 1. As shown in FIG. 3, no sharp corner is present in the inner circumference of the stress alleviating portion 14 in a plan view. Particularly, in the present embodiment, the stress alleviating portion 14 is formed with an approximately constant width. No sharp corner is also present in the outer circumference of the stress alleviating portion 14 in a plan view.

Returning to FIGS. 1 and 2, the semiconductor 20 is flip-chip mounted on the wiring substrate 10. That is, the semiconductor chip 20 is mounted on the wiring substrate 10 with the conductive bump 30 disposed in between. A UBM (Under Bump Metal) 22 is mounted in the semiconductor chip 20. The conductive bump 30 is connected with the wiring (not shown in the drawing) of the semiconductor chip 20 via the UBM 22. The gap between the wiring substrate 10 and the semiconductor chip 20 is filled with the under-fill resin 40. The values of the degree of elasticity (Young's modulus) of the semiconductor chip 20 and the under-fill resin 40 are, for example, 100 to 200 GPa and 5 to 10 GPa, respectively.

The conductive bump 30 is connected with the electrode pad 16 through the above-described opening 12a. A contacting area between the conductive bump 30 and the electrode pad 16 is approximately equal to the bottom area (the area of the exposed portion of the electrode pad 16) of the opening 12a in the present embodiment. This means that the construction in which the approximate entire of the opening 12a is filled with the conductive bump 30 is formed. As the material of the conductive bump 30, for example, a solder, copper (Cu), or gold (Au) can be used.

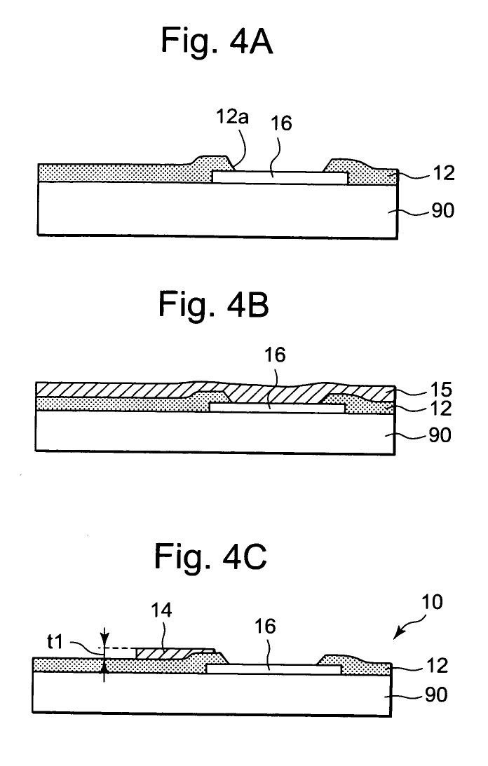

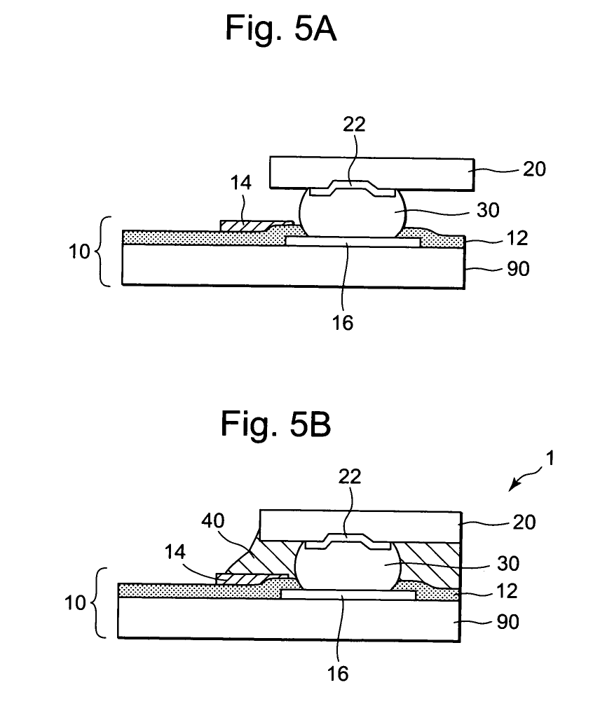

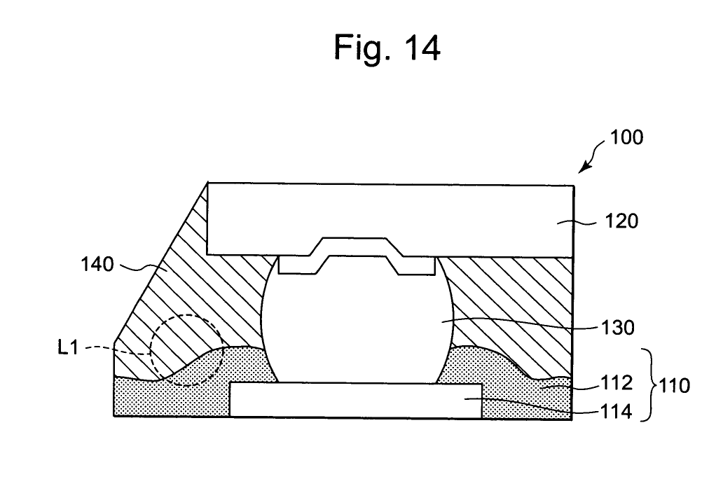

Referring to FIGS. 4 and 5, as an embodiment of the semiconductor device production method according to the present invention, an example of a method for producing the semiconductor device 1 will be described. The solder resist layer 12 having the opening 12a is first formed on a base body 90 (FIG. 14(a)). Thereafter, a resin 15 which constructs the stress alleviating portion 14 is applied on the solder resist layer 12 (FIG. 14(b)). In the present example, the resin 15 is applied over the entire surface of the solder resist layer 12 including the opening 12a. Application of the resin 15 can be carried out by printing, dipping, or roll coating. The resin 15 is preferably a thermosetting resin.

Then, the stress alleviating portion 14 is formed by patterning the resin 15. That is, the resin 15 is removed except for that located in the area opposed to the semiconductor chip 20. As a result, the wiring substrate 10 is obtained (FIG. 4(c)). The patterning can be carried out by exposing and developing the resin in a case where a photosensitive resin is employed as the resin 15. The thickness t1 of the stress alleviating portion 14 is considered to be, for example, about 30 μm.

Subsequently, the semiconductor 20 is mounted on the wiring substrate 10 with the conductive bump 30 disposed in between (FIG. 5A). Thereafter, the gap between the wiring substrate 10 and the semiconductor chip 20 is filled with the under-fill resin 40. Through the above described processes, the semiconductor device 1 is obtained (FIG. 5B). In FIG. 1, the diagrammatic representation of the base body 90 is omitted.

The advantages of the present embodiment will be described. A stress alleviating portion 14 is mounted in the area of the solder resist layer 12 opposed to the outer circumference of the semiconductor chip 20 in the present embodiment. The stress alleviating portion 14 alleviates the stress acting on the solder resist layer 12 and the under-fill resin 40. As a result, peeling is hardly occurred at the interface between the solder resist layer 12 and the under-fill resin 40.

The stress acting on the conductive bump 30 is also alleviated by the stress alleviating portion 14. Therefore, a reliability of the connection of the conductive bump 30 with the electrode pad 16 is improved. Particularly, when a construction in which the approximate entire of the opening 12a of the solder resist layer 12 is filled with the conductive bump 30 is formed as in the present embodiment, there is little gap between the solder resist layer 12 and the conductive bump 30. As a result, a stress tends to be transmitted from the solder resist layer 12 to the conductive bump 30 as compared to a case where the solder resist layer 12 and the conductive bump 30 are spaced apart from each other. Therefore, when the construction is formed, it is particularly useful to mount the stress alleviating portion 14 to enhance the connection reliability of the conductive bump 30.

Furthermore, the presence of the stress alleviating portion 14 can inhibit the under-fill resin 40 injected in the gap between the wiring substrate 10 and the semiconductor chip 20 from flowing out of the gap. As a result, the filet shape of the under-fill resin 40 can be scaled down.

The stress alleviating portion 14 is constructed as a resin layer. Therefore, the stress alleviating portion 14 can easily be formed. The degree of elasticity of the stress alleviating portion 14 is lower than that of the solder resist layer 12. As a result, an effect of alleviating a stress is further enhanced by the stress alleviating portion 14.

No sharp corner is present in the inner circumference of the stress alleviating portion 14 in a plan view. When a sharp corner is present, a stress is concentrated there. When a stress is concentrated in a particular area in such a manner, a possibility for a crack to be created from the area as a starting point is increased. From this viewpoint, in the present embodiment, no sharp corner is present in the inner circumference of the stress alleviating portion 14. As a result, a stress is diffused. Therefore, a crack can be inhibited from being occurred. Furthermore, no sharp corner is present in the outer circumference of the stress alleviating portion 14, so a crack is further inhibited from being occurred.

In the present embodiment, as described in FIGS. 4(b) and 4(c), after applying the resin 15 over the entire surface of the solder resist layer 12, the resin 1S is patterned to form the stress alleviating portion 14. By such a method, the stress alleviating portion 14 is easily formed. Alternatively, in FIG. 4(b), the resin 15 may be applied only in the area of the solder resist layer 12 opposed to the outer circumference of the semiconductor chip 20. This allows a process of patterning the resin 15 to be able to be eliminated.

### Embodiment 2

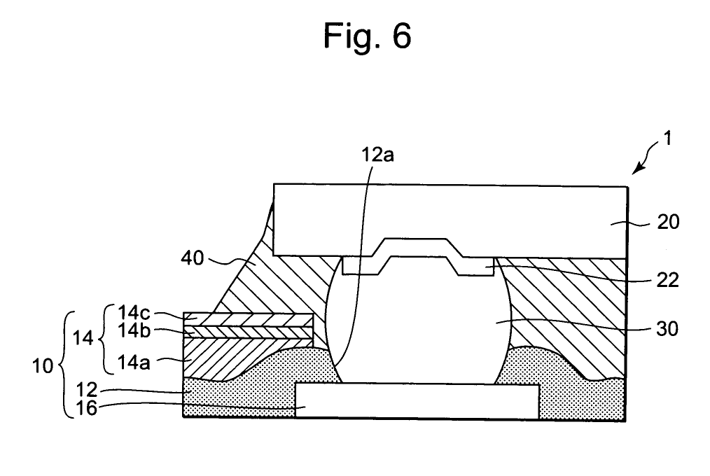

FIG. 6 is a cross-sectional view showing a second embodiment of the semiconductor device according to the present invention. In a semiconductor device 2, the stress alleviating portion 14 is constructed of a resin layer 14a (the first resin layer), a resin layer 14b (the second resin layer), and resin layer 14c (the third resin layer). On the resin layer 14a, the resin layer 14b and resin layer 14c are sequentially laminated. The degree of elasticity of the resin layer 14b is lower than that of the resin layer 14a. The degree of elasticity of the resin layer 14c is lower than that of the resin layer 14b. That is, a relationship of the degree of elasticity of the resin layer 14a>the degree of elasticity of the resin layer 14b>the degree of elasticity of the resin layer 14c is established. The other construction of the semiconductor device 2 is the same as that of the semiconductor device 1 in FIG. 1.

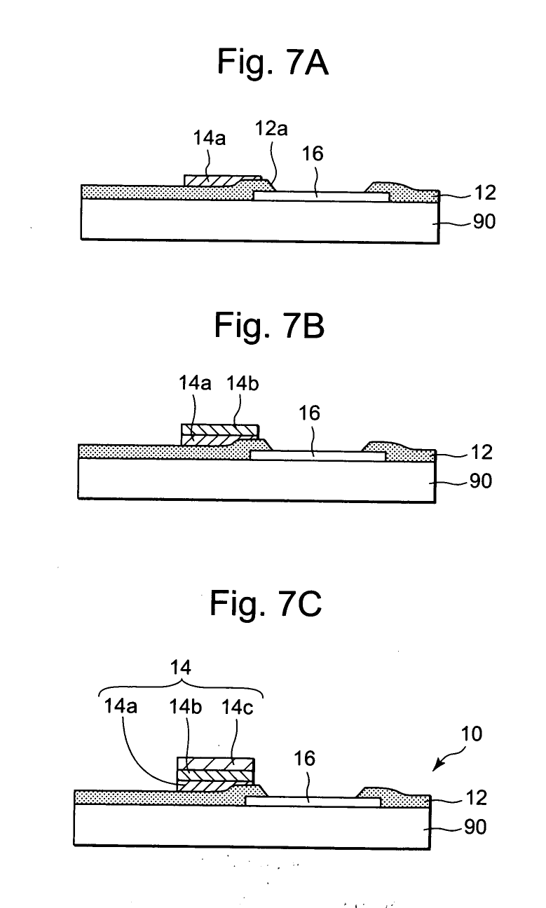

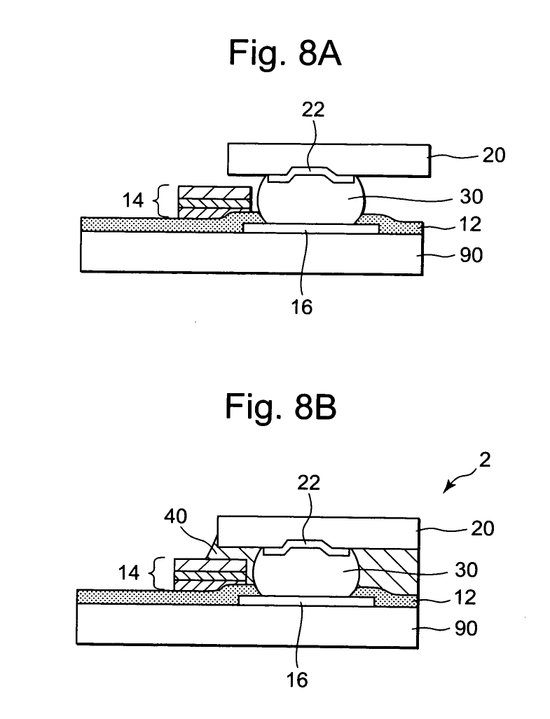

Referring to FIGS. 7 and 8, an example of the production method of the semiconductor device 2 will be described. First, the solder resist layer 12 having the opening 12a is formed on the base body 90. Subsequently, a resin layer 14a is formed on the solder resist layer 12 (FIG. 7A). The resin layer 14a can be formed by the same method as that for the stress alleviating portion 14 of, for example, the first embodiment (refer to FIG. 4B and FIG. 4C).

Thereafter, a resin layer 14b is formed only on the resin layer 14a (FIG. 7(b)). The formation of the resin layer 14b can be carried out by, for example, a printing method utilizing a printing mask. Alternatively, the resin layer 14b may selectively be formed on the resin layer 14a by a curtain method. Thereafter, the resin layer 14b is thermally cured or light-cured. Subsequently, the resin layer 14c is formed by the same method as that for the resin layer 14b. Through these processes, the wiring substrate 10 is obtained (FIG. 7C).

Then, the semiconductor chip 20 is mounted on the wiring substrate 10 with the conductive bump 30 disposed in between (FIG. 8A). Thereafter, the gap between the wiring substrate 10 and the semiconductor chip 20 is filled with the under-fill resin 40. Through the above processes, the semiconductor device 2 is obtained (FIG. 8B). In FIG. 6, the diagrammatic representation of the base body 90 is omitted.

In the present embodiment, it is intended that, by constructing the stress alleviating portion 14 of a number of resin layers having a different degree of elasticity from each other (resin layers 14a, 14b and 14c), the degree of elasticity of the stress alleviating portion 14 is gradually reduced as the resin layer becomes closer to the semiconductor chip 20. By this method, an effect of alleviating a stress can further be enhanced by the stress alleviating portion 14. Therefore, the peeling at the interface between the solder resist layer 12 and the under-fill resin 40 is effectively inhibited. At the same time, the connection reliability of the conductive bump 30 is further improved. The other advantages of the present embodiment are the same as those in the first embodiment.

### Embodiment 3

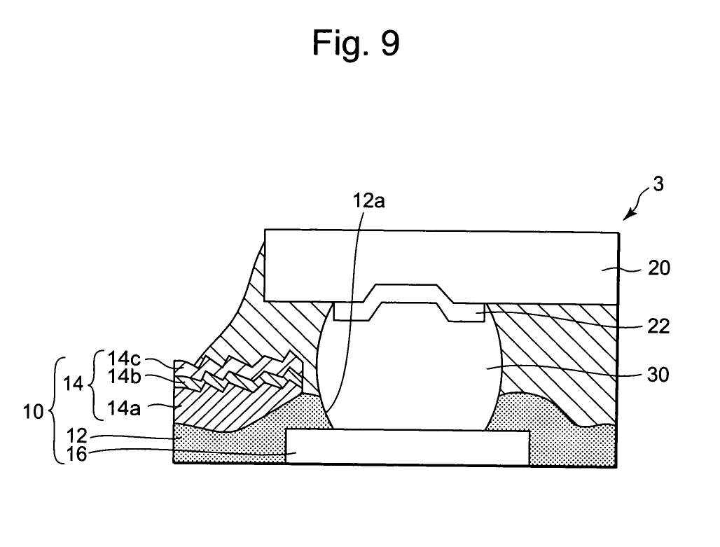

FIG. 9 is a cross-sectional view showing a third embodiment of the semiconductor device according to the present invention. In a semiconductor 3, the top surface of the stress alleviating portion 14 (the top surface of the resin layer 14c) is a rough surface. The interface between the resin layers 14a and 14b, and the interface between the resin layers 14b and 14c are also rough. The rough surface referred to here preferably has roughness of an Ra value of 0.4 μm or more. In the present embodiment, any of the Ra values of the top surface of the stress alleviating portion 14, the interface between the resin layers 14a and 14b, and the interface between the resin layers 14b and 14c is about 0.5 to several μm. On the contrary, the Ra value of the solder resist layer 12 is 0.1 to 0.3 μm. The other construction of the semiconductor device 3 is the same as that of the semiconductor device 2 in FIG. 6.

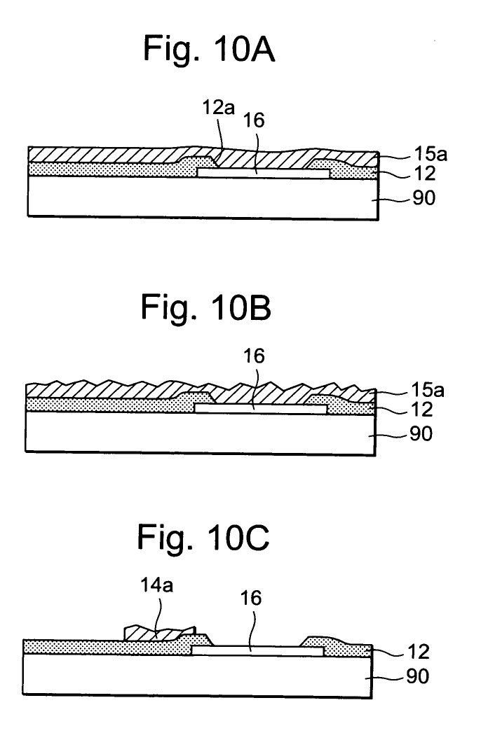

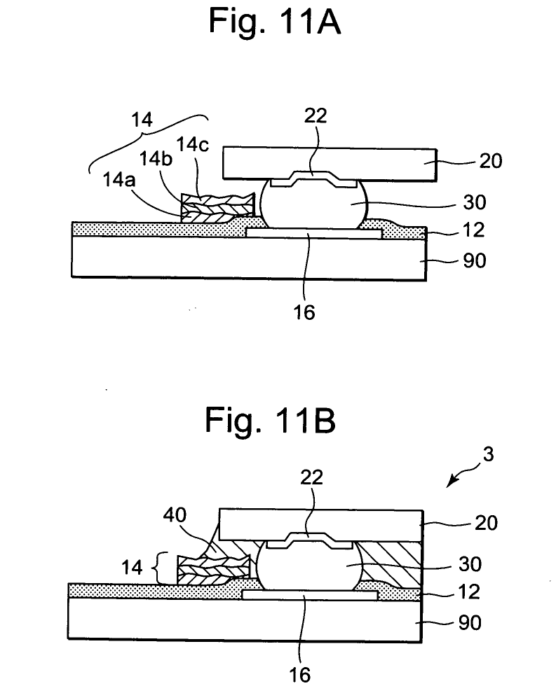

Referring to FIGS. 10 and 11, an example of the production method of the semiconductor device 3 will be described. First, the solder resist layer 12 having the opening 12a is formed on the base body 90. Thereafter, a resin 15a which constructs resin layer 14a is formed on the solder resist layer 12 (FIG. 10A). The resin 15a can be formed by the same method as that for the resin 15 in FIG. 4B). Subsequently, the surface of the resin 15a is roughened (FIG. 10B). The roughening can be carried out by means of, for example, blasting, or desmearing.

Then, the resin layer 14a is formed by patterning the resin 15a (FIG. 10C). In consideration of the fact that the surface of the resin 15a has been roughened, the patterning is preferably carried out by means of non-contact exposure and developing.

Thereafter, the resin layers 14b and 14c are sequentially formed by the same method as that for resin layer 14a. Furthermore, the semiconductor chip 20 is mounted on the wiring substrate 10 with the conductive bump 30 disposed in between (FIG. 1 IA). Subsequently, the gap between the wiring substrate 10 and the semiconductor chip 20 is filled with the under-fill resin 40. By the above processes, the semiconductor device 3 is obtained (FIG. 11B). In FIG. 9, the diagrammatic representation of the base body 90 is omitted.

In the present embodiment, the top surface of the stress alleviating portion 14 is a rough surface. As a result, the under-fill resin 40 injected in the gap between the wiring substrate 10 and the semiconductor chip 20 can more effectively be inhibited from flowing out of the gap by the stress alleviating portion 14. The interface between the resin layers 14a and 14b is also a rough surface. This roughness allows the improvement in the adhesion between the resin layers 14a and 14b. The same is true in the interface between the resin layers 14b and 14c. The other advantages of the present embodiment are the same as those in the second embodiment.

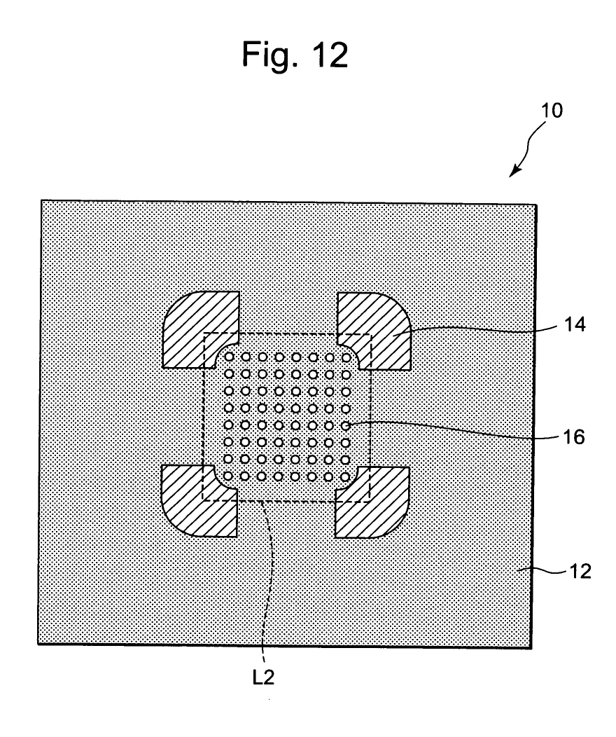

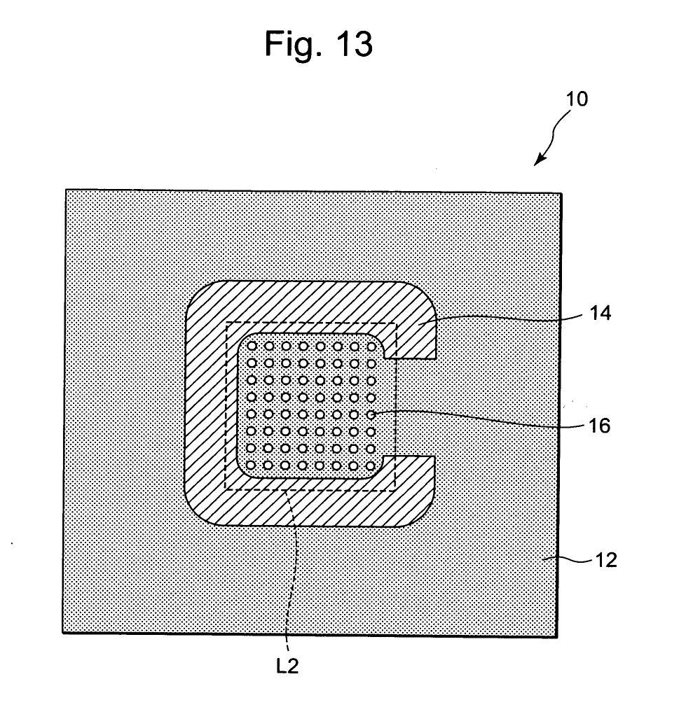

The present invention is not limited to the embodiments, and allows various modifications. For example, in the embodiments, an example in which the stress alleviating portion 14 is mounted over the entire of the outer circumference of the semiconductor chip 20 is shown. Alternatively, the stress alleviating portion 14 may be mounted over a part of the outer circumference. In this case, as shown in FIGS. 12 and 13, the stress alleviating portion 14 is preferably disposed at the four corners of the semiconductor chip 20. This is because a stress is particularly large at the four corners of the outer circumference of the semiconductor chip 20. In these figures, the outer circumference of the semiconductor chip 20 is represented by a dotted line L2.

In the example in FIG. 12, the stress alleviating portion 14 is mounted only in the areas opposed to the four corners of the semiconductor chip 20. In the example in FIG. 13, the stress alleviating portion 14 is broken in an area opposed to a side of the semiconductor chip 20. By injecting an under-fill from the area in which the stress alleviating portion 14 is broken, the injection tends to easily be carried out. The shape of the stress alleviating potion 14 in FIG. 13 is called a C character-shape.

In the embodiments, an example in which the conductive bump 30 is mounted while contacting the solder resist layer 12 is shown. Alternatively, the conductive bump 30 may be mounted while being spaced apart from the solder resist layer 12. That is, a contact area of the conductive bump 30 with the electrode pad 16 may be smaller as compared to the area of the bottom surface of the opening 12a.

In FIGS. 6 and 9, examples in which the stress alleviating portion 14 is constructed of three resin layers are shown. Alternatively, the stress alleviating portion 14 may be constructed of either two resin layers or four resin layers or more.

Further, it is noted that, Applicant's intent is to encompass equivalents of all claim elements, even if amended later during prosecution

What is claimed is:

1. A semiconductor device, comprising:
a wiring substrate;
a semiconductor chip mounted on the wiring substrate with a conductive bump disposed in between;
a solder resist layer formed on the wiring substrate,
an under-fill resin which fills a gap between the wiring substrate and the semiconductor chip, and
a stress alleviating portion which is formed on the solder resist layer at an area opposed to an outer circumference of the semiconductor chip, the stress alleviating portion comprises a material different from that of the solder resist layer, thereby to alleviate a stress acting on the solder resist layer and the under-fill resin.

2. The semiconductor device according to claim 1, wherein the stress alleviating portion comprises a resin layer.

3. The semiconductor device according to claim 1, wherein a degree of elasticity of the stress alleviating portion is lower than that of the solder resist layer.

4. The semiconductor device according to claim 1, wherein an inner circumference, in a plan view, of the stress alleviating portion comprises a structure other than a sharp corner.

5. The semiconductor device according to claim 1, wherein the stress alleviating portion includes a first resin layer and a second resin layer formed on the first resin layer.

6. The semiconductor device according to claim 5, wherein a degree of elasticity of the second resin layer is lower than that of the first resin layer.

7. The semiconductor device according to claim 5, wherein an interface between the first resin layer and the second resin layer comprises a rough surface.

8. The semiconductor device according to claim 1, wherein a top surface of the stress alleviating portion comprises a rough surface.

9. The semiconductor device according to claim 1, wherein the stress alleviating portion is arranged only outside of the conductive bump.

10. A wiring substrate for mounting a semiconductor chip with a conductive bump, comprising:
a solder resist layer; and
a stress alleviating portion formed on the solder resist layer at an area opposed to an outer circumference of the semiconductor chip, and the stress alleviating portion being comprising a material different from that of the solder resist layer.

11. A method of forming a semiconductor device, comprising:
forming a solder resist layer on a wiring substrate;
forming a stress alleviating portion comprising a material different from that of the solder resist layer on the solder resist layer, at an area being opposed to an outer circumference of a semiconductor chip,
mounting said semiconductor chip on the wiring substrate with a conductive bump,
filling a gap between the wiring substrate and the semiconductor chip with an under-fill resin.

12. The semiconductor production method according to claim 11, wherein said forming the stress alleviating portion includes:
applying a resin which comprises a constituent material of the stress alleviating portion on the solder resist layer; and
removing a first portion of the resin while leaving a second portion of the resin located in the area.

13. The semiconductor production method according to claim 11, wherein said forming the stress alleviating portion includes applying a resin which is a constituent material of the stress alleviating portion only to the area of the solder resist layer.

14. A method for producing a wiring substrate for mounting a semiconductor chip with a conductive bump, comprising:
forming a solder resist layer; and
forming a stress alleviating portion comprises a material different from that of the solder resist layer on the solder resist layer, at an area being opposed to an outer circumference of the semiconductor chip.

15. A wiring substrate, comprising:
a base body including a central potion and a peripheral potion surrounding said central portion;
a plurality of electrode pads formed on said central portion of said base body without being formed on said peripheral portion of said base body;
a solder resist layer formed on said central portion and said peripheral portion of said base body while exposing top surfaces of said plurality of electrode pads; and
a stress alleviating layer formed on the solder resist layer only at a boundary area of said central portion and said peripheral portion, and the stress alleviating portion comprising a material different from that of the solder resist layer.

16. The wiring substrate as claimed in claim 15, wherein said stress alleviating layer includes a ring-shape to surround said plurality of electrode pads.

17. The wiring substrate as claimed in claim 15, wherein said stress alleviating layer includes a C-shape to mostly surround said plurality of electrode pads.

18. The wiring substrate as claimed in claim 15, wherein said plurality of electrode pads are arranged in a matrix, and said stress alleviating layer includes a plurality of portions arranged at corners of said matrix.
